(19) United States
(12) Patent Application Publication
(10) Pub. No.: US 2026/0304713 A1
(43) Pub. Date: Oct. 1, 2026

(54) HEAT DISSIPATION ASSEMBLY STRUCTURE

(71) Applicant: Delta Electronics, Inc., Taoyuan City (TW)

(72) Inventors: Shangyong Hong, Shanghai (CN); Xuefeng Lu, Shanghai (CN); Yanggui Feng, Shanghai (CN)

(21) Appl. No.: 19/090,791

(22) Filed: Mar. 26, 2025

(51) Int. Cl. H05K 7/20

(52) U.S. Cl. CPC H05K 7/209

(57) ABSTRACT

A heat dissipation assembly structure is disclosed and includes a circuit board, a power module, a semiconductor device, CPO devices, a substrate and a heat dissipation component. The circuit board includes a first surface and a second surface. The power module is disposed on the first surface. The semiconductor device is disposed on the second surface and spatially corresponding to the power module. The power module and the semiconductor device are electrically connected through the circuit board. The CPO devices are disposed on the second surface and arranged adjacent to the semiconductor device. The substrate includes an opening, a third surface and a fourth. The opening passes through the third surface and the fourth surface, the fourth surface faces the first surface, and the power module is exposed through the opening. The heat dissipation component includes a first heat dissipation element thermally coupled to the power module.

### FIELD OF THE INVENTION

The present disclosure relates to a power electronics technology field, and more particularly to a heat dissipation assembly structure.

### BACKGROUND OF THE INVENTION

As an important component of power conversion, the modern power electronic devices are widely used in the power, electronics, motor and energy industries. With the development of power electronics technology, higher requirements are placed on the power level, the power density and the modularity of high-power switching power supplies. The module layout of power electronic devices also takes into account the requirements of high power density and heat dissipation efficiency.

In addition, as the signal transmission rates and transmission bandwidths are increased in the data communications field, the power supply current required by a Co-Packaged Optics (CPO) module is also increased. The power supply of the conventional CPO module adopts the horizontal power supply. That is, one or more voltage regulators and CPO modules (including semiconductor devices, CPO devices and circuit boards) are arranged on the same surface of the substrate, so that the voltage regulator can provide the power to the CPO module during operation. On the other hand, a heat sink is provided above the voltage regulator and the integrated circuit, so that all the heat loss generated by the voltage regulator module and the integrated circuit during operation is taken away by the above heat sink. However, as the power level of CPO modules is gradually increased, the horizontal power supply mode fails to meet the requirements of application performance. Since the circuit connection distance from the voltage regulator to the CPO module has to be lengthened constantly in the horizontal power supply architecture, the direct current resistance (DCR) generated therefrom will reach more than 100 μΩ, which may cause the overall power supply efficiency of the system to drop by more than 10%. Such a significant efficiency reduction is not only an obstacle to improving the system power level, but also brings great difficulties to the overall heat dissipation design.

Therefore, there is a need of providing a heat dissipation assembly structure with a heat dissipation component for vertical power supply application, so as to improve the heat dissipation efficiency of a power module in a limited space, simplify the heat dissipation component assembly manufacturing process, reduce the costs and obviate the drawbacks encountered by the prior arts.

### SUMMARY OF THE INVENTION

An object of the present disclosure is to provide a heat dissipation assembly structure. In the present disclosure, the power module and the semiconductor device are arranged on two opposite sides of the circuit board. When the circuit board and the substrate are assembled to form a vertical power supply design, the power module on the circuit board is exposed through an opening on the substrate, and cooperated with the heat dissipation element of the heat dissipation component thermally coupled to the contact surface of the power module and the contact surface of the semiconductor device, respectively, so that a two-way heat dissipation mechanism is formed. In this way, the heat dissipation efficiency of power modules in limited space is improved in vertical power supply applications, the assembling and manufacturing process of the heat dissipation component is simplified, and the costs are reduced. Notably, the power module including the voltage regulator and the semiconductor device including the integrated circuit are respectively arranged on two opposite sides of the circuit board. That is, the architecture of the heat dissipation assembly structure in the present disclosure is a vertical power supply application, which can greatly reduce the electrical connection distance from the power module to the semiconductor device, thereby greatly reducing the DC resistance generated therefrom, reducing the power loss, and greatly improving the power supply efficiency. In addition, the vertical stacking structure of the power module and the semiconductor device makes the overall design more compact and reduces the space occupancy of the entire system. Thereby, the terminal-use applications are more flexible. On the other hand, the heat dissipation component in the heat dissipation assembly structure may include a first heat dissipation element and a second heat dissipation element, which are thermally coupled to the contact surface of the power module and the contact surface of the semiconductor device, respectively, so that the heat dissipation mode in the vertical power supply application is expanded to two sides. The available space of the heat dissipation device is greatly increased. With the improvement of the efficiency of vertical power supply applications between the circuit board and the substrate, the substrate further includes an opening in the region corresponding to the power module, so that the heat dissipation component for bidirectional heat dissipation is directly fit the contact surface of the power module and the contact surface of the semiconductor device, and the heat generated by the power module and the semiconductor device is more effectively dissipated. Thereby, the temperature of the entire integrated system is reduced and the performance of the integrated system is improved.

Another object of the present disclosure is to provide a heat dissipation assembly structure. When the circuit board is connected to the substrate such as a system board through a conductive portion or a connector, the space between the power module and the substrate is limited. By using the opening design of the substrate, the heat dissipation component is combined with the stacking structure of the vertical power supply application to form a two-way heat dissipation mechanism, so that the heat dissipation problem of the heat dissipation component is solved effectively. Furthermore, since the heat dissipation element of the heat dissipation component is attached to the contact surface of the power module through the opening of the substrate, the depth of the power module relative to the opening can be adjusted, or a thermal interface material layer can be added. Furthermore, the heat dissipation requirements of the substrate can also be combined to simplify the heat dissipation assembly, reduce the module costs, and enhance the product competitiveness. The heat dissipation element of the heat dissipation component is not limited to an air-cooled heat sink or a liquid-cooled heat sink. In addition, when the circuit board and the substrate are stacked for vertical power supply, the docking distance between the circuit board and the substrate may be limited by the height of the connector. The opening of the substrate is utilized to avoid interference in the vertical direction between the heat dissipation component and the substrate in the vertical stacking structure of the heat dissipation component and the power module. Thereby, the overall height of the heat dissipation assembly structure is reduced after assembly, and the heat dissipation problem in a restricted space is solved effectively.

In accordance with an aspect of the present disclosure, a heat dissipation assembly structure is provided and includes a circuit board, a power module, a semiconductor device, a plurality of CPO devices, a substrate and a heat dissipation component. The circuit board includes a first surface and a second surface arranged opposite to each other. The power module is disposed on the first surface of the circuit board. The semiconductor device is disposed on the second surface of the circuit board and spatially corresponding to the power module. The power module and the semiconductor device are electrically connected through the circuit board. The plurality of CPO devices are disposed on the second surface of the circuit board and arranged adjacent to the semiconductor device. The substrate includes an opening and a third surface and a fourth surface arranged opposite to each other. The opening passes through the third surface and the fourth surface, the fourth surface faces the first surface of the circuit board, and a contact surface of the power module is exposed through the opening. The heat dissipation component includes a first heat dissipation element. The first heat dissipation element is thermally coupled to the contact surface of the power module.

In accordance with another aspect of the present disclosure, a heat dissipation assembly structure is provided and includes a circuit board, a power module, a semiconductor device, a substrate, a conductive portion or a connector, and a heat dissipation component. The circuit board includes a first surface and a second surface arranged opposite to each other. The power module is disposed on the first surface of the circuit board. The semiconductor device is disposed on the second surface of the circuit board and spatially corresponding to the power module. The power module and the semiconductor device are electrically connected through the circuit board. The substrate includes an opening and a third surface and a fourth surface arranged opposite to each other, wherein the opening passes through the third surface and the fourth surface, the fourth surface faces the first surface of the circuit board, and a contact surface of the power module is exposed through the opening. The conductive portion or the connector is disposed between the first surface of the circuit board and the fourth surface of the substrate. The heat dissipation component includes a first heat dissipation element. The first heat dissipation element is thermally coupled to the contact surface of the power module.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is an exploded structural view illustrating a heat dissipation assembly structure according to a first embodiment of the present disclosure;

FIG. 2 is an exploded structural view illustrating the heat dissipation assembly structure according to the first embodiment of the present disclosure from another perspective;

FIG. 3 is a structural perspective view illustrating the heat dissipation assembly structure according to the first embodiment of the present disclosure;

FIG. 4 is a transverse-cross sectional view illustrating the heat dissipation assembly structure according to the first embodiment of the present disclosure;

FIG. 5 is an exploded structural view illustrating a heat dissipation assembly structure according to a second embodiment of the present disclosure;

FIG. 6 is an exploded structural view illustrating the heat dissipation assembly structure according to the second embodiment of the present disclosure from another perspective;

FIG. 7 is a structural perspective view illustrating the heat dissipation assembly structure according to the second embodiment of the present disclosure;

FIG. 8 is a transverse-cross sectional view illustrating the heat dissipation assembly structure according to the second embodiment of the present disclosure;

FIG. 9 is an exploded structural view illustrating a heat dissipation assembly structure according to a third embodiment of the present disclosure;

FIG. 10 is an exploded structural view illustrating the heat dissipation assembly structure according to the third embodiment of the present disclosure from another perspective;

FIG. 11 is a structural perspective view illustrating the heat dissipation assembly structure according to the third embodiment of the present disclosure;

FIG. 12 is a transverse-cross sectional view illustrating the heat dissipation assembly structure according to the third embodiment of the present disclosure;

FIG. 13 is an exploded structural view illustrating a heat dissipation assembly structure according to a fourth embodiment of the present disclosure;

FIG. 14 is an exploded structural view illustrating the heat dissipation assembly structure according to the fourth embodiment of the present disclosure from another perspective;

FIG. 15 is a structural perspective view illustrating the heat dissipation assembly structure according to the fourth embodiment of the present disclosure; and

FIG. 16 is a transverse-cross sectional view illustrating the heat dissipation assembly structure according to the fourth embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “under,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

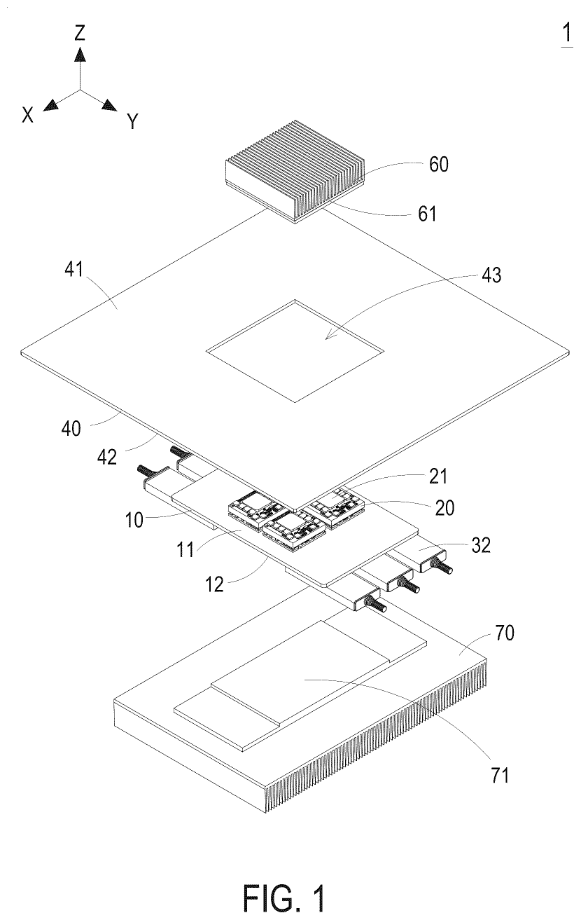

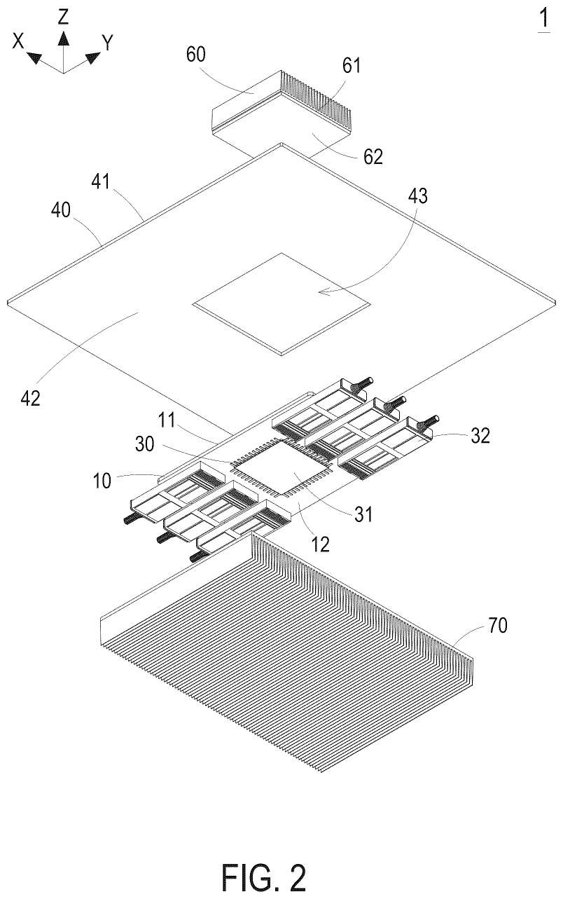

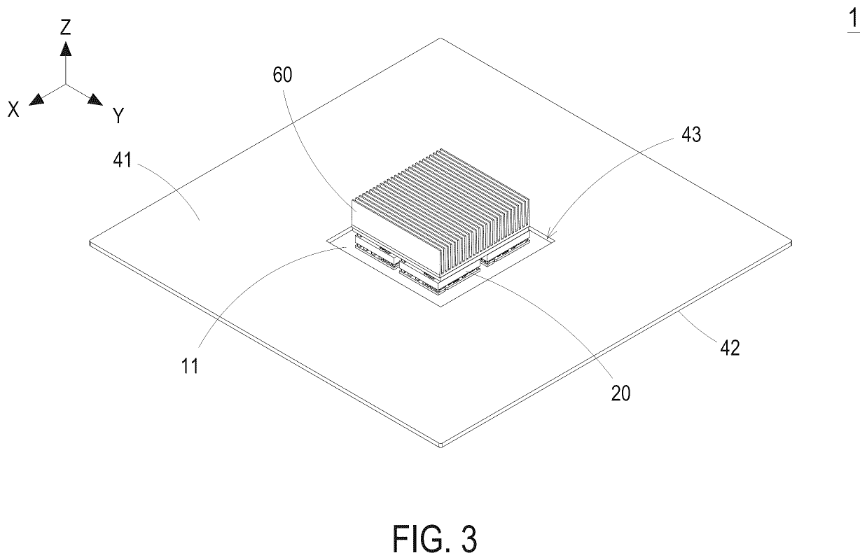

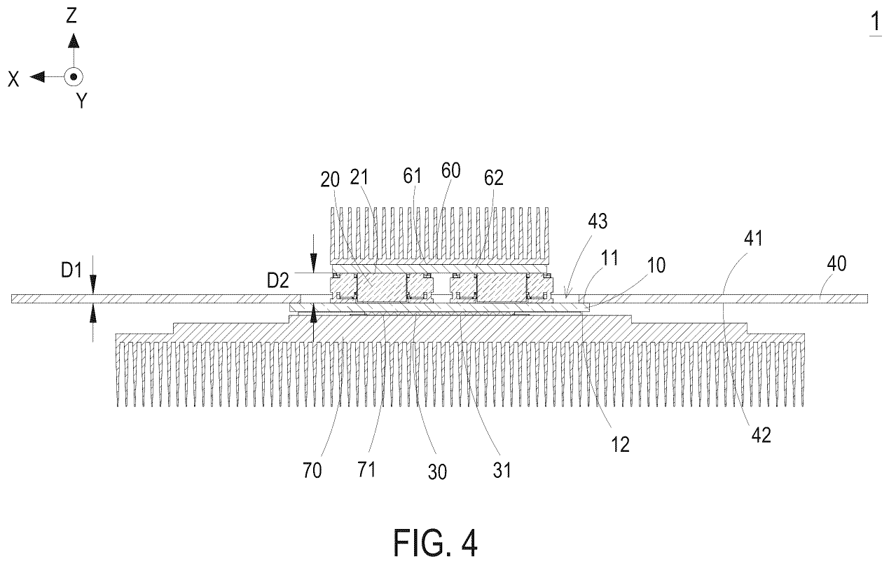

FIG. 1 and FIG. 2 are exploded structural views illustrating a heat dissipation assembly structure according to a first embodiment of the present disclosure. FIG. 3 is a structural perspective view illustrating the heat dissipation assembly structure according to the first embodiment of the present disclosure. FIG. 4 is a transverse-cross sectional view illustrating the heat dissipation assembly structure according to the first embodiment of the present disclosure. The present disclosure provides a heat dissipation assembly structure 1 to cooperate with vertical power supply applications and solve the heat dissipation problem during vertical power supply. In the embodiment, the heat dissipation assembly structure 1 for vertical power supply applications includes a circuit board 10, a power module 20, a semiconductor device 30, a plurality of CPO devices 32, a substrate 40 and a heat dissipation component. The circuit board 10 includes a first surface 11 and a second surface 12 arranged opposite to each other. In some embodiments, the power module 20 includes at least one voltage regulator, and is disposed on the first surface 11 of the circuit board 10. In the embodiment, the semiconductor device 30 is disposed on the second surface 12 of the circuit board 10 and spatially corresponding to the power module 20. The power module 20 and the semiconductor device 30 are electrically connected through the circuit board 10. The plurality of CPO devices 32 are disposed on the second surface 12 of the circuit board 10 and arranged adjacent to the semiconductor device 30. Notably, the power module 20 and the semiconductor device 30 are respectively arranged on the first surface 11 and the second surface 12 of the circuit board 10, and the first surface 11 and the second surface 12 are arranged opposite to each other, and the power module 20 and the semiconductor device 30 are further electrically connected through a conductive through hole (not shown) of the circuit board 10, so that the power module 20 can further provide electrical energy to the semiconductor device 30 when powered on. Since the power module 20 and the semiconductor device 30 are stacked on the circuit board 10 to achieve the vertical power supply application, the electrical connection distance between the power module 20 and the semiconductor device 30 is reduced sufficiently. Therefore, the Direct Current (DC) resistance between the power module 20 and the semiconductor device 30 is greatly reduced, the power loss is reduced, and the power supply efficiency is greatly improved. Furthermore, the power module 20 is electrically connected to the circuit board 10 through a plurality of conductive portions (not shown) arranged in a matrix. In some embodiments, the conductive portions include a plurality of positive output terminals and a plurality of negative output terminals, which are used for the power module 20 to provide the electrical energy to the semiconductor device 30. In the embodiment, the output positive terminals and the output negative terminals are misaligned in a staggered arrangement, so as to further reduce parasitic losses in the energy transfer path and improve the efficiency of energy transmission. At the same time, due to the reduction in line losses, the heat consumption is greatly reduced, and the pressure on heat dissipation of vertical power supply application system is greatly relieved.

In the embodiment, the substrate 40 is a terminal-use application system board electrically connected to the circuit board 10, and includes a third surface 41, a fourth surface 42 and an opening 43. The third surface 41 and the fourth surface 42 are arranged opposite to each other. The opening 43 passes through the third surface 41 and the fourth surface 42. When the circuit board 10 is assembled with the substrate 40, the opening 43 is spatially corresponding to the power module 20 disposed on the circuit board 10. When the substrate 40 is combined with the circuit board 10, the fourth surface 42 of the substrate 40 faces the first surface 11 of the circuit board 10, and the first surface 11 of the circuit board 10 and the fourth surface 42 of the substrate 40 are in contact and connected with each other. In the embodiment, the first surface 11 of the circuit board 10 and the fourth surface 42 of the substrate 40 are both provided with at least one conductive portion, and the conductive portion on the fourth surface 42 is disposed and corresponding to the conductive portion on the first surface 11. The fourth surface 42 of the substrate 40 and the first surface 11 of the circuit board 10 are bonded together through the conductive portions, so as to achieve the fixed connection and electrical connection between the substrate 40 and the circuit board 10. If the conductive portion is not provided, in the embodiment, at least one connector is arranged between the fourth surface 42 of the substrate 40 and the first surface 11 of the circuit board 10, and the substrate 40 and the circuit board 10 are fixed by the at least one connector, so that the electrical connection between the substrate 40 and the circuit board 10 is achieved by the connector. Furthermore, a contact surface 21 of the power module 20 is further exposed through the opening 43.

In the embodiment, the heat dissipation component includes a first heat dissipation element 60 and a second heat dissipation element 70 spatially corresponding to the power module 20 and the semiconductor device 30, respectively. In the embodiment, the first heat dissipation element 60 is an air-cooled heat sink, and includes an attached surface 61 thermally coupled to the contact surface 21 of the power module 20 through the opening 43 of the substrate 40. In the embodiment, the second heat dissipation element 70 is an air-cooled heat sink, and includes an attached surface 71 thermally coupled to a contact surface 31 of the semiconductor device 30. In the embodiment, the heat dissipation component further includes a thermal interface material layer 62 disposed between the contact surface 21 of the power module 20 and the attached surface 61 of the first heat dissipation element 60. Thereby, through the arrangement of the thermal interface material layer 62, the thermal resistance in the heat transfer path is reduced and the influence of dimensional tolerances is improved. In the embodiment, the thermal interface material layer 62 is a thermally conductive insulation pad, a thermally conductive insulation glue or a thermally conductive copper block. In some embodiments, the thermal interface material layer 62 is made of thermally conductive silicone or resin. Since the polymer has a certain flexibility, it allows to provide a certain buffering effect when the heat dissipation component, the circuit board 10 and the substrate 40 in the heat dissipation assembly structure 1 are fixedly connected and compressed. In other embodiments, the thermal interface material layer 62 may be omitted, or disposed between the contact surface 31 of the semiconductor device 30 and the attached surface 71 of the second heat dissipation element 70. Notably, the power module 20 and the semiconductor device 30 are vertically stacked on the circuit board 10 (along the Z-axis direction), and it makes the overall design more compact. The first heat dissipation element 60 and the second heat dissipation element 70 are thermally coupled to the contact surface 21 of the power module 20 and the contact surface 31 of the semiconductor device 30 in two opposite directions. The heat dissipation mode is expanded in vertical power supply applications to form a two-way heat dissipation mechanism. The heat generated from the power module 20 is quickly dissipated upward through the first heat dissipation element 60, and the heat generated from the semiconductor device 30 is quickly dissipated downward through the second heat dissipation 70, so that the temperature of the entire integrated system is greatly reduced and the performance of the integrated system is improved.

In the embodiment, along the vertical direction (i.e., the Z-axis direction), the second heat dissipation element 70, the semiconductor device 30, the circuit board 10, the power module 20, the substrate 40 and the first heat dissipation element 60 are stacked in sequence from bottom to top. With the arrangement of the opening 43 on the substrate 40, it allows to avoid interference between the first heat dissipation element 60 and the substrate 40 in the vertical direction, so that the overall height of the heat dissipation assembly structure 1 is further reduced after assembly, and the heat dissipation problem in a limited space is solved effectively. In the embodiment, in conjunction with the two-side heat dissipation of the vertical power supply application, a horizontal projection of the second heat dissipation element 70 on the first surface 11 of the circuit board 10, a horizontal projection of the semiconductor device 30 on the first surface 11 of the circuit board 10, a horizontal projection of the power module 20 on the first surface 11 of the circuit board 10, a horizontal projection of the opening 43 on the first surface 11 of the circuit board 10, and a horizontal projection of the first heat dissipation element 60 on the first surface 11 of the circuit board 10 are at least partially overlapped.

In the embodiment, the first surface 11 of the circuit board 10 is attached to the fourth surface 42 of the substrate 40, and the first surface 11 and the fourth surface 42 have the same horizontal height. A distance D1 from the third surface 41 of the substrate 40 to the first surface 11 of the circuit board 10 is equal to the thickness of the substrate 40. A distance D2 from the contact surface 21 of the power module 20 to the first surface 11 of the circuit board 10 is equal to the thickness of the power module 20. In the embodiment, the distance D2 from the contact surface 21 of the power module 20 to the first surface 11 of the circuit board 10 is greater than the distance D1 from the third surface 41 of the substrate 40 to the first surface 11 of the circuit board 10, so the contact surface 21 of the power module 20 passes through the opening 43 and is exposed. In the embodiment, the horizontal projection of the first heat dissipation element 60 on the first surface 11 of the circuit board 10 is included in the horizontal projection of the opening 43 on the first surface 11 of the circuit board 10. That is, the area of the attached surface 61 of the first heat dissipation element 60 is smaller than the area of the opening 43, and it allows to form the thermal contact with the contact surface 21 of the power module 20 directly, and form the thermal contact with the contact surface 21 of the power module 20 through the thermal interface material layer 62. Certainly, in other embodiments, the connection position between the attached surface 61 of the first heat dissipation element 60 and the contact surface 21 of the power module 20 can be adjusted according to the depth of the power module 20 relative to the opening 43.

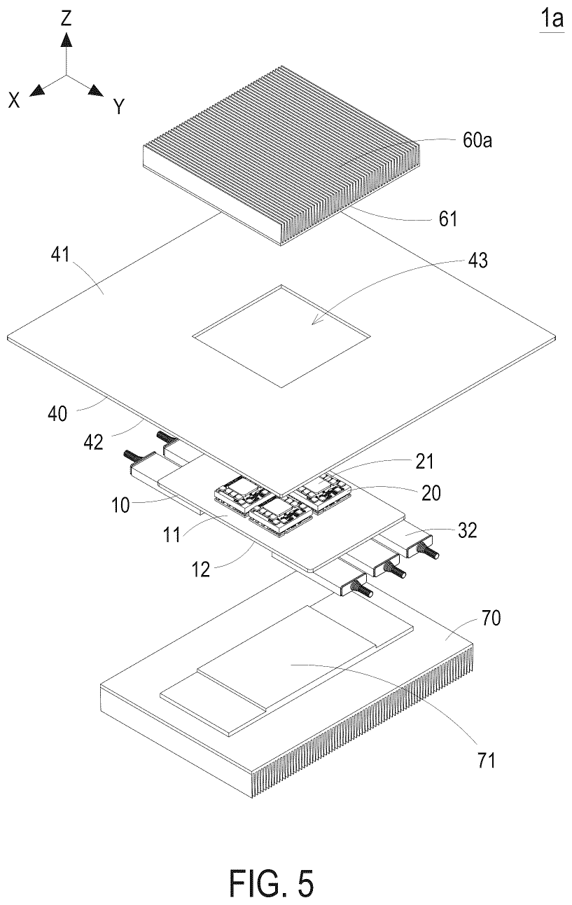

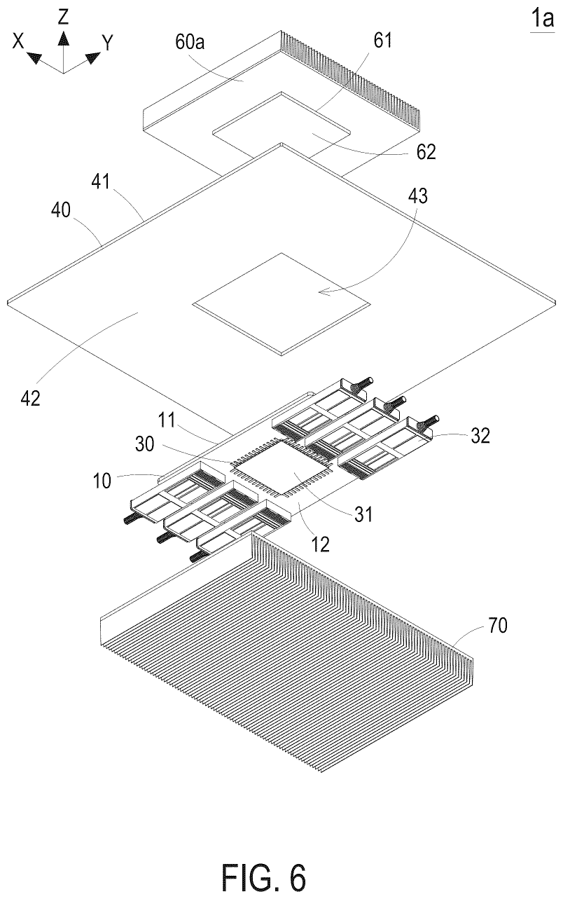

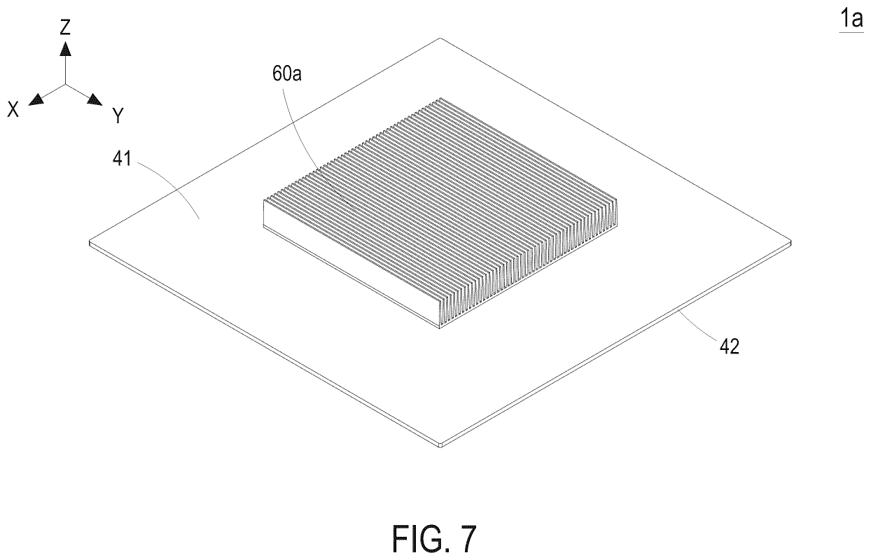

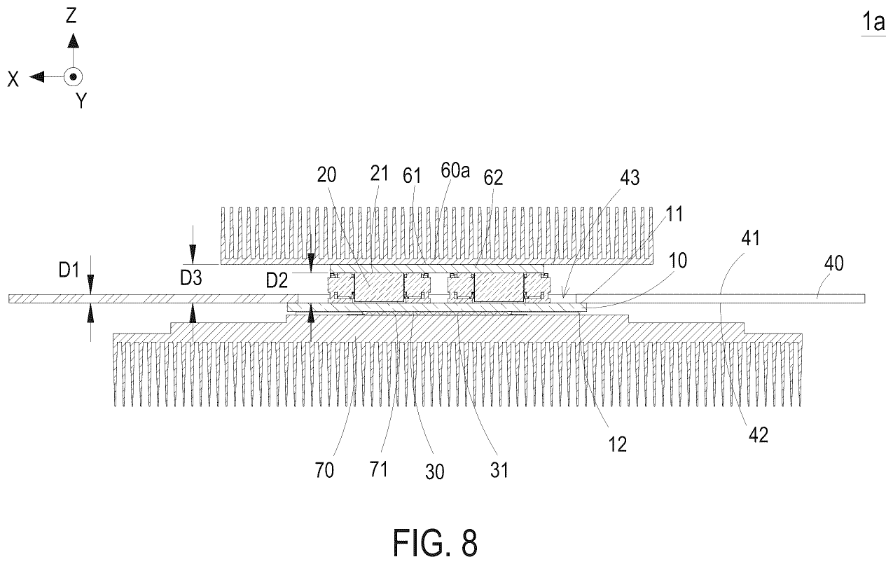

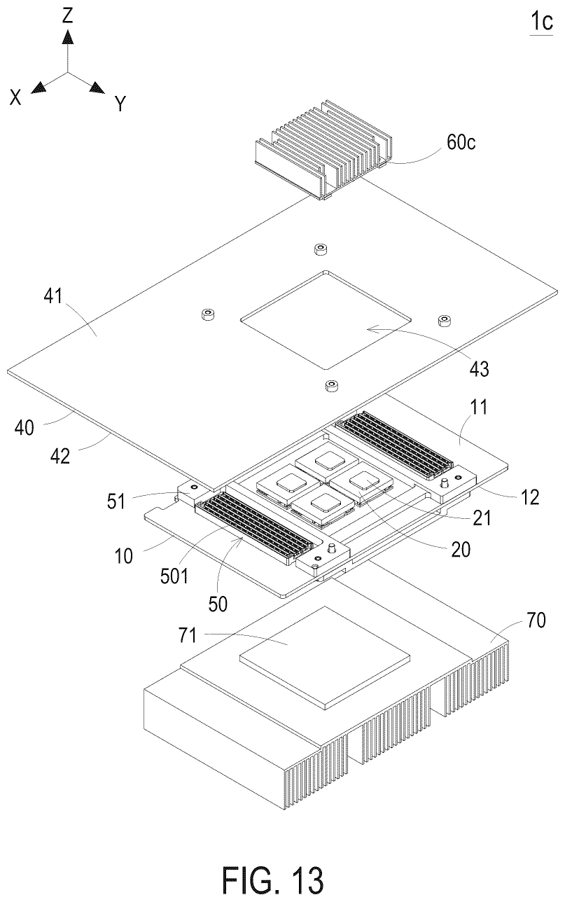

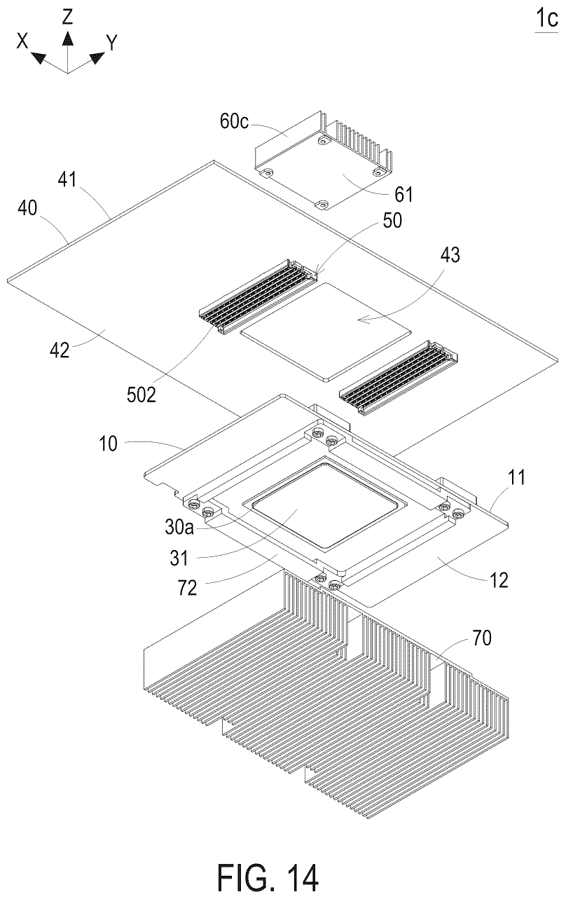

FIG. 5 and FIG. 6 are exploded structural views illustrating a heat dissipation assembly structure according to a second embodiment of the present disclosure. FIG. 7 is a structural perspective view illustrating the heat dissipation assembly structure according to the second embodiment of the present disclosure. FIG. 8 is a transverse-cross sectional view illustrating the heat dissipation assembly structure according to the second embodiment of the present disclosure. In the embodiment, the structures, elements and functions of the heat dissipation assembly structure 1a are similar to those of the heat dissipation assembly structure 1 of FIG. 1 to FIG. 4, and are not redundantly described herein. In the embodiment, the distance D2 from the contact surface 21 of the power module 20 to the first surface 11 of the circuit board 10 is greater than the distance D1 from the third surface 41 of the substrate 40 to the first surface 11 of the circuit board 10, and the contact surface 21 of the power module 20 passes through the opening 43 to be exposed. In the embodiment, the first surface 11 of the circuit board 10 and the fourth surface 42 of the substrate 40 are both provided with at least one conductive portion, and the conductive portion on the fourth surface 42 is disposed and corresponding to the conductive portion on the first surface 11. The fourth surface 42 of the substrate 40 and the first surface 11 of the circuit board 10 are attached through the conductive portions, and the substrate 40 and the circuit board 10 are fixedly connected and electrically connected. If the conductive portion is not provided, in the embodiment, at least one connector is arranged between the fourth surface 42 of the substrate 40 and the first surface 11 of the circuit board 10, and the substrate 40 and the circuit board 10 are fixed by the at least one connector (Referring to the connector 50 in the fourth embodiment shown in FIG. 13 and FIG. 14,) so that the electrical connection between the substrate 40 and the circuit board 10 is achieved by the connector. In some embodiments, the substrate 40 further provides the input power to the power module 20 through the connector and the circuit board 10. At the same time, the connector is utilized to realize the signal transmission and data transmission between the substrate 40 and the circuit board 10. In other embodiments, the connector provides mechanical support for the substrate 40 and the circuit board 10. In addition, a distance D3 from the attached surface 61 of the first heat dissipation element 60a to the first surface 11 of the circuit board 10 is greater than a distance D1 from the third surface 41 of the substrate 40 to the first surface 11 of the circuit board 10. The power module 20 is partially protruded from the third surface 41 of the substrate 40. The thermal interface material layer 62 and the first heat dissipation element 60a are both located outside the opening 43. When the attached surface 61 of the first heat dissipation element 60a is thermally coupled to the contact surface 21 of the power module 20 through the thermal interface material layer 62, it is not affected by the interference of the substrate 40. In the embodiment, the horizontal projection of the opening 43 on the first surface 11 of the circuit board 10 is included in the horizontal projection of the first heat dissipation element 60a on the first surface 11 of the circuit board 10. That is, the area of the attached surface 61 of the first heat dissipation element 60a is greater than the area of the opening 43. In the embodiment, the first heat dissipation element 60a is an air-cooled heat sink, which is arranged above the third surface 41 of the substrate 40 and extended horizontally along the XY plane, so that the attached surface 61 of the first heat dissipation element 60a can cover the opening 43 and a portion of the third surface 41. Thereby, when the attached surface 61 of the first heat dissipation element 60a is thermally coupled to the contact surface 21 of the power module 20 through the thermal interface material layer 62, it is further combined with the heat dissipation requirements of other electronic devices (not shown) on the third surface 41 of the substrate 40 to achieve the thermal contact connection. Thus, the heat dissipation assembly process is simplified, the module costs are reduced, and the product competitiveness is enhanced.

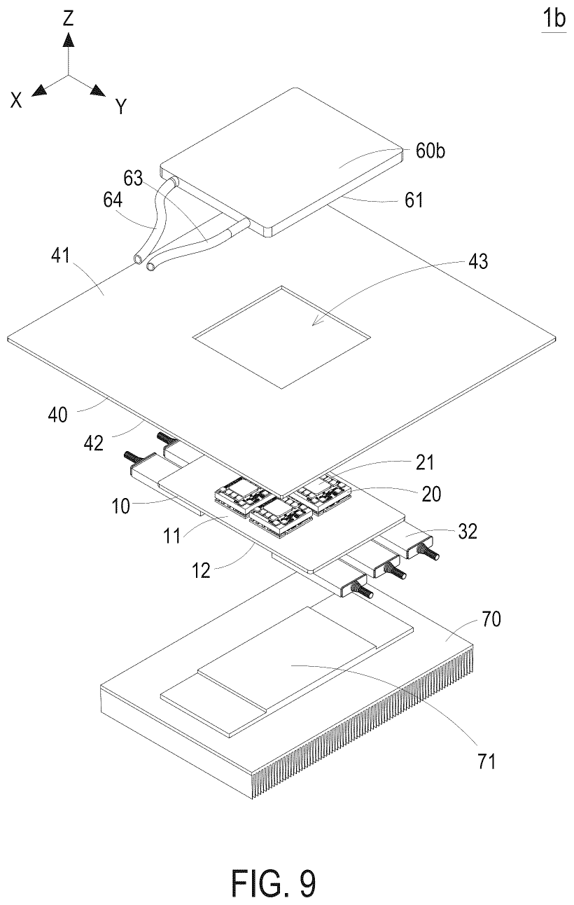

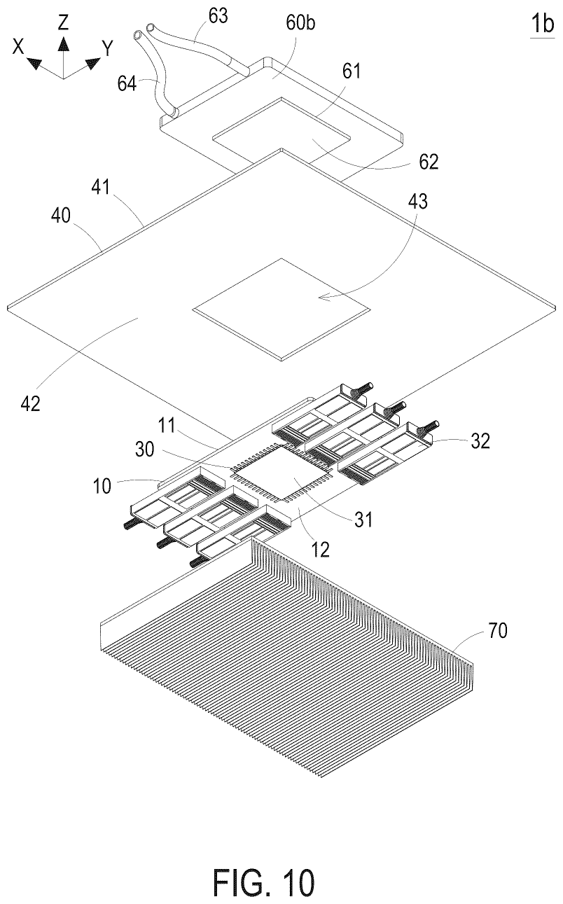

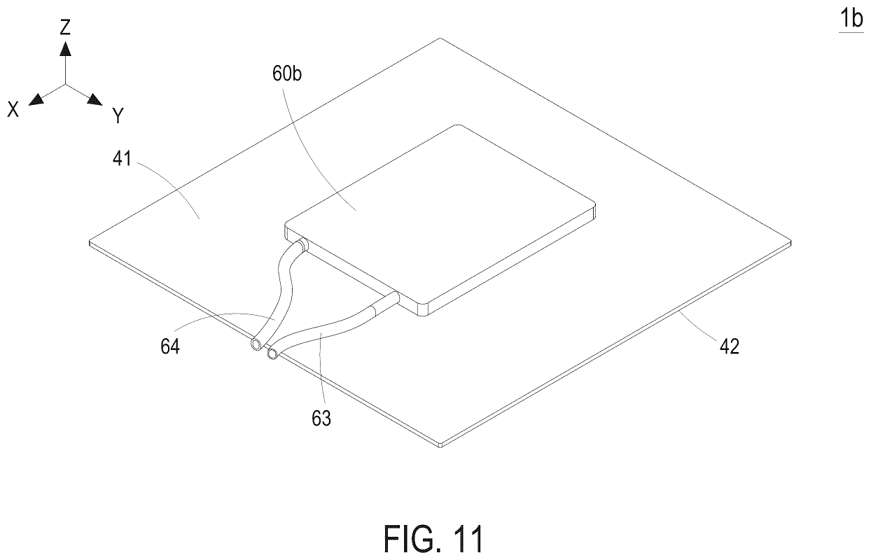

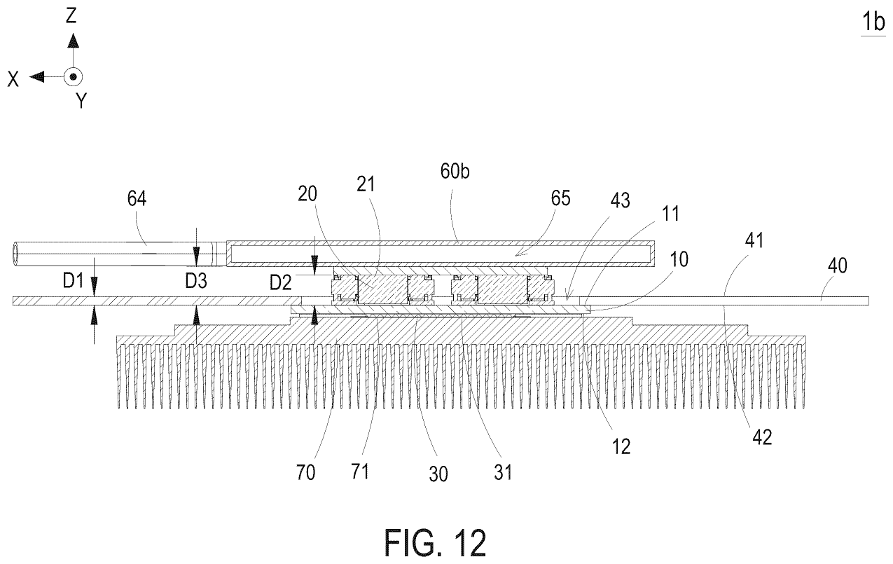

FIG. 9 and FIG. 10 are exploded structural views illustrating a heat dissipation assembly structure according to a third embodiment of the present disclosure. FIG. 11 is a structural perspective view illustrating the heat dissipation assembly structure according to the third embodiment of the present disclosure. FIG. 12 is a transverse-cross sectional view illustrating the heat dissipation assembly structure according to the third embodiment of the present disclosure. In the embodiment, the structures, elements and functions of the heat dissipation assembly structure 1b are similar to those of the heat dissipation assembly structure 1 of FIG. 1 to FIG. 4, and are not redundantly described herein. In the embodiment, the first heat dissipation element 60b of the heat dissipation assembly structure 1b is a liquid-cooled heat sink, including an inlet tube 63, an outlet tube 64 and a liquid cooling chamber 65. The inlet tube 63 and the outlet tube 64 are in fluid communication with to the liquid cooling chamber 65, and located on one side of the first heat dissipation element 60b. In the embodiment, the openings of the inlet tube 63 and the outlet tube 64 face toward the X-axis direction. In the embodiment, the coolant (not shown) in the liquid cooling chamber 65 is circulated through the inlet tube 63 and the outlet tube 64, so as to achieve the cooling effect. In the embodiment, the attached surface 61 of the first heat dissipation element 60b is thermally coupled to the contact surface 21 of the power module 20 through the thermal interface material layer 62, so that the heat generated from the power module 20 is removed through the coolant in the liquid cooling chamber 65.

In the embodiment, the fourth surface 42 of the substrate 40 is attached to the first surface 11 of the circuit board 10, and the distance D2 from the contact surface 21 of the power module 20 to the first surface 11 of the circuit board 10 is greater than the distance D1 from the third surface 41 of the substrate 40 to the first surface 11 of the circuit board 10, so that the contact surface 21 of the power module 20 passes through the opening 43 and is exposed. In addition, the distance D3 from the attached surface 61 of the first heat dissipation element 60b to the first surface 11 of the circuit board 10 is greater than the distance D1 from the third surface 41 of the substrate 40 to the first surface 11 of the circuit board 10. The power module 20 is partially protruded from the third surface 41 of the substrate 40. The thermal interface material layer 62 and the first heat dissipation element 60b are both located outside the opening 43. In that, when the attached surface 61 of the first heat dissipation element 60b is thermally coupled to the contact surface 21 of the power module 20 through the thermal interface material layer 62, it is not affected by the interference of the substrate 40. In other embodiments, the protrusion height of the attached surface 61 of the first heat dissipation element 60b relative to the third surface 41 of the substrate 40 is controlled by increasing the thickness of the thermal interface material layer 62. It can also be combined with the heat dissipation requirements of other electronic devices (not shown) on the third surface 41 of the substrate 40 to achieve the thermal contact connection. Thus, the heat dissipation assembly process is simplified, the module costs are reduced, and the product competitiveness is enhanced.

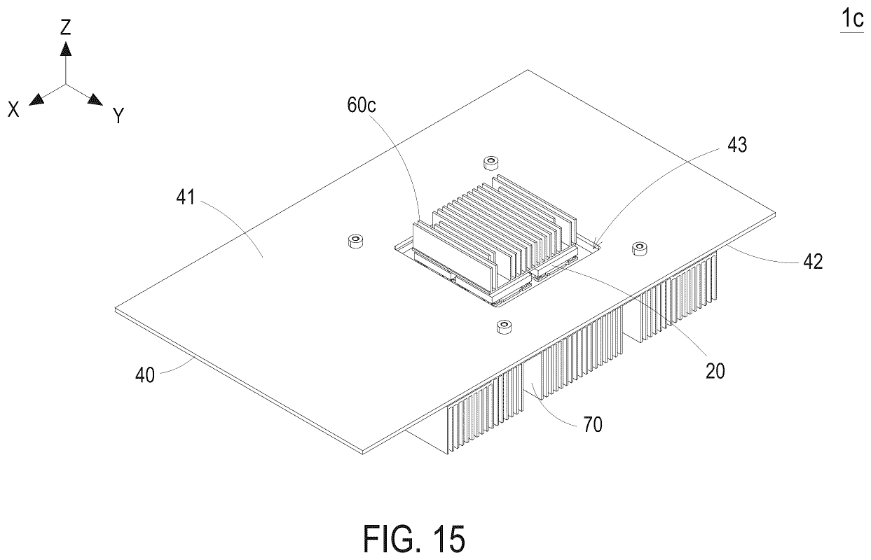

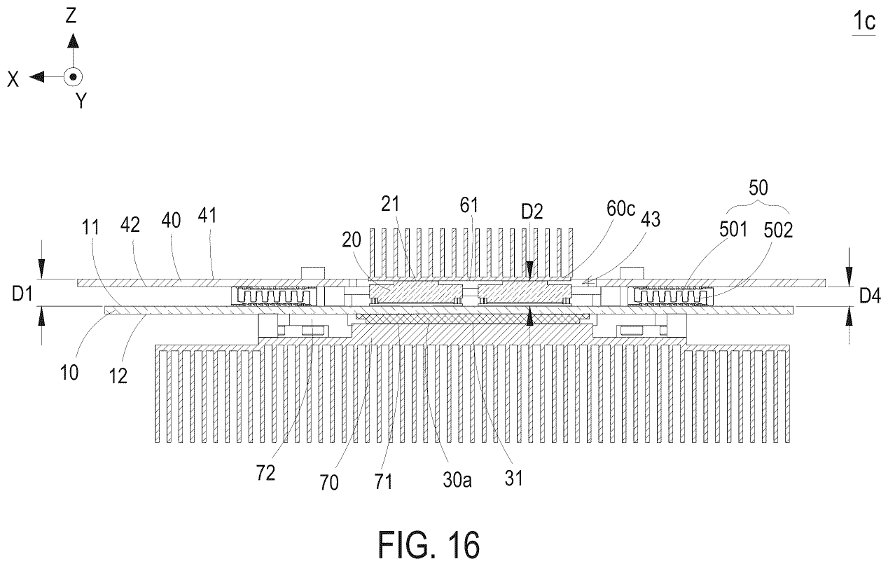

FIG. 13 and FIG. 14. are exploded structural views illustrating a heat dissipation assembly structure according to a fourth embodiment of the present disclosure. FIG. 15 is a structural perspective view illustrating the heat dissipation assembly structure according to the fourth embodiment of the present disclosure. FIG. 16 is a transverse-cross sectional view illustrating the heat dissipation assembly structure according to the fourth embodiment of the present disclosure. In the embodiment, the structures, elements and functions of the heat dissipation assembly structure 1c are similar to those of the heat dissipation assembly structure 1 of FIG. 1 to FIG. 4, and are not redundantly described herein. In the embodiment, the heat dissipation assembly structure 1c includes a circuit board 10, a power module 20, a semiconductor device 30a, a substrate 40, a connector 50 and a heat dissipation component. In some embodiments, the power module 20 includes at least one voltage regulator, and is disposed on the first surface 11 of the circuit board 10. In the embodiment, the semiconductor device 30a is disposed on the second surface 12 of the circuit board 10 and spatially corresponding to the power module 20. In some embodiments, the semiconductor device 30a is a graphics processing unit (GPU) chip, a central processing unit (CPU) chip, an application-specific integrated circuit (ASIC) chip, a field programmable gate array (FPGA) chip or a semiconductor die having the above functions. Notably, the power module 20 and the semiconductor device 30a are respectively arranged on the first surface 11 and the second surface 12 of the circuit board 10 which are arranged opposite to each other, and the power module 20 and the semiconductor device 30a are further electrically connected through a conductive through hole (not shown) of the circuit board 10, so that the power module 20 can further provide electrical energy to the semiconductor device 30a when powered on. Since the power module 20 and the semiconductor device 30a are stacked on the circuit board 10 to achieve the vertical power supply application, the electrical connection distance between the power module 20 and the semiconductor device 30a is reduced sufficiently. Therefore, the DC resistance between the power module 20 and the semiconductor device 30a is greatly reduced, the power loss is reduced, and the power supply efficiency is greatly improved. Furthermore, the power module 20 is electrically connected to the circuit board 10 through a plurality of conductive portions arranged in a matrix. In some embodiments, the connector 50 can be replaced by the conductive portions include a plurality of positive output terminals and a plurality of negative output terminals, which are used for the power module 20 to provide the electrical energy to the semiconductor device 30a. In the embodiment, the output positive terminals and the output negative terminals are misaligned in a staggered arrangement, so as to further reduce parasitic losses in the energy transfer path and improve the efficiency of energy transmission. At the same time, due to the reduction in line losses, the heat consumption is greatly reduced, and the pressure on heat dissipation of vertical power supply application system is greatly relieved.

In the embodiment, the substrate 40 is an terminal-use application system board electrically connected to the circuit board 10, and includes a third surface 41, a fourth surface 42 and an opening 43. The third surface 41 and the fourth surface 42 are arranged opposite to each other. The opening 43 passes through the third surface 41 and the fourth surface 42, and is spatially corresponding to the power module 20 disposed on the circuit board 10. When the substrate 40 and the circuit board 10 are combined with each other, the fourth surface 42 of the substrate 40 faces the first surface 11 of the circuit board 10. Furthermore, a contact surface 21 of the power module 20 is partially or completely exposed through the opening 43. In the embodiment, the circuit board 10 and the substrate 40 are connected through a connector 50, so that the circuit board 10 and the substrate 40 are electrically connected and exchange the power, the computing data and the control signals. In some embodiments, the substrate 40 further provides the input power to the power module 20 through the connector 50 and the circuit board 10, and the connector 50 is utilized to realize the signal transmission and data transmission between the substrate 40 and the circuit board 10. Furthermore, the connector 50 provides the mechanical support for the substrate 40 and the circuit board 10. In the embodiment, the connector 50 is disposed between the first surface 11 of the circuit board 10 and the fourth surface 42 of the substrate 40. In the embodiment, the connector 50 includes a first connection element 501 and a second connection element 502. In the embodiment, the first connection element 501 is disposed on the first surface 11 of the circuit board 10 and arranged adjacent to the power module 20, and the second connection element 502 is disposed on the fourth surface 42 of the substrate 40 and arranged adjacent to a lateral edge of the opening 43. The heat dissipation assembly structure 1c further includes a support frame 51 disposed adjacent to the connector 50, so that a fixed height is maintained when the connector 50 is connected between the substrate 40 and the circuit board 10. In other words, a distance D4 from the first surface 11 of the circuit board 10 to the fourth surface 42 of the substrate 40 is, for example, equal to the height of the connector 50. Certainly, the form, the connection method and the arrangement of the connector 50 are adjustable according to the practical requirements, and the present disclosure is not limited thereto. In another embodiment, the connector 50 includes a connection element, an end of the connection element is fixed and electrically connected to one of the substrate 40 and the circuit board 10, and the other end of the connection element is in contact with and electrically connected to the other of the substrate 40 and the circuit board 10.

In the embodiment, the heat dissipation component includes a first heat dissipation element 60c and a second heat dissipation element 70 spatially corresponding to the power module 20 and the semiconductor device 30a, respectively. In the embodiment, the first heat dissipation element 60c is an air-cooled heat sink, and includes an attached surface 61 thermally coupled to the contact surface 21 of the power module 20 through the opening 43 of the substrate 40. In the embodiment, the second heat dissipation element 70 is an air-cooled heat sink, and includes an attached surface 71 thermally coupled to a contact surface 31 of the semiconductor device 30a. In the embodiment, the heat dissipation component further includes a fixing frame 72, which is arranged between the second heat dissipation element 70 and the second surface 12 of the circuit board 10 and located at an outer periphery of the semiconductor device 30a. In that, the second heat dissipation element 70 can be installed and fixed through the fixing frame 72. Notably, the power module 20 and the semiconductor device 30a are vertically stacked on the circuit board 10 (along the Z-axis direction), and it makes the overall design more compact. The first heat dissipation element 60c and the second heat dissipation element 70 are thermally coupled to the contact surface 21 of the power module 20 and the contact surface 31 of the semiconductor device 30a in two opposite directions. The heat dissipation mode is expanded in vertical power supply applications to form a two-way heat dissipation mechanism. The heat generated from the power module 20 is quickly dissipated upward through the first heat dissipation element 60c, and the heat generated from the semiconductor device 30a is quickly dissipated downward through the second heat dissipation 70, so that the temperature of the entire integrated system is greatly reduced and the performance of the integrated system is improved.

In the embodiment, along the vertical direction (i.e., the Z-axis direction), the second heat dissipation element 70, the semiconductor device 30a, the circuit board 10, the power module 20, the substrate 40 and the first heat dissipation element 60c are stacked in sequence from bottom to top. With the arrangement of the opening 43 on the substrate 40, it allows to avoid interference between the first heat dissipation element 60c and the substrate 40 in the vertical direction, so that the overall height of the heat dissipation assembly structure 1c is further reduced after assembly, and the heat dissipation problem in a limited space is solved effectively. In the embodiment, in conjunction with the two-side heat dissipation of the vertical power supply application, a horizontal projection of the second heat dissipation element 70 on the first surface 11 of the circuit board 10, a horizontal projection of the semiconductor device 30a on the first surface 11 of the circuit board 10, a horizontal projection of the power module 20 on the first surface 11 of the circuit board 10, a horizontal projection of the opening 43 on the first surface 11 of the circuit board 10, and a horizontal projection of the first heat dissipation element 60c on the first surface 11 of the circuit board 10 are at least partially overlapped.

Furthermore, in this embodiment, since at least one of the power module 20 and the first heat dissipation element 60c are at least partially accommodated within the range enclosed by the opening 43, the interference with the substrate 40 in the vertical stacking direction (i.e., the Z-axis direction) can be avoided. Thereby, the overall height of the heat dissipation assembly structure 1c is reduced after assembly, and the overall power density is improved. In the embodiment, the distance D2 from the contact surface 21 of the power module 20 to the first surface 11 of the circuit board 10 is smaller than the distance D1 from the third surface 41 of the substrate 40 to the first surface 11 of the circuit board 10, and is greater than the distance D4 from the fourth surface 42 to the first surface 11 of the circuit board 10, so that the power module 20 is at least partially accommodated within the opening 43. Similarly, the distance D2 from the attached surface 61 of the first heat dissipation element 60c to the first surface 11 of the circuit board 10 is equal to the distance D2 from the contact surface 21 of the power module 20 to the first surface 11 of the circuit board 10, so that the first heat dissipation element 60c is at least partially accommodated within the opening 43. In the embodiment, the horizontal projection of the first heat dissipation element 60c on the first surface 11 of the circuit board 10 is included in the horizontal projection of the opening 43 on the first surface 11 of the circuit board 10. That is, the area of the attached surface 61 of the first heat dissipation element 60c is smaller than the area of the opening 43, and it allows to form the thermal contact with the contact surface 21 of the power module 20 directly through the opening 43. In other embodiments, the connection position between the attached surface 61 of the first heat dissipation element 60c and the contact surface 21 of the power module 20 can be adjusted according to the depth of the power module 20 relative to the opening 43.

From the above, when the power module 20 and the semiconductor device 30 are vertically stacked on the opposite sides of the circuit board 10 or the power module 20 and the semiconductor device 30a are vertically stacked on the opposite sides of the circuit board 10, and then connected to, for example, the substrate 40 of the terminal-use application system, the power supply requirements and the signal connection of the power module 20 and the semiconductor device 30 or the integrated circuit in the semiconductor device 30a can be realized. The power supply energy can be input vertically, and the signal transmission of the semiconductor device 30 or the integrated circuit in the semiconductor device 30a with the substrate 40 can be realized. Notably, in the embodiment, after the circuit board 10 in the heat dissipation assembly structure 1~1c is assembled to the substrate 40, the contact surface 21 of the power module 20 is exposed through the opening 43. In that, it allows adjusting the attached surface 61 of the first heat dissipation element 60~60c according to the depth of the power module 20 relative to the opening 43, setting the thermal interface material layer 62, or being combined with the heat dissipation requirements on the third surface 43 of the substrate 40 to achieve the requirement of thermal coupling to the contact surface 21 of the power module 20, while avoiding the interference between the heat dissipation component and the substrate 40 in the vertical direction (i.e., the Z-axis direction). Thereby, the overall height of the heat dissipation assembly structure 1~1c is reduced after assembly, and the heat dissipation problem in the limited space is solved effectively. Furthermore, in some embodiments, the circuit board 10 and the substrate 40 can be directly attached to each other, or connected through a conductive portion or a connector 50. The present disclosure is not limited thereto, and not redundantly described hereafter.

In summary, the present disclosure provides a heat dissipation assembly structure. The power module and the semiconductor device are arranged on two opposite sides of the circuit board. When the circuit board and the substrate are assembled to form a vertical power supply design, the power module on the circuit board is exposed through an opening on the substrate, and cooperated with the heat dissipation element of the heat dissipation component thermally coupled to the contact surface of the power module and the contact surface of the semiconductor device, respectively, so that a two-way heat dissipation mechanism is formed. In this way, the heat dissipation efficiency of power modules in limited space is improved in vertical power supply applications, the assembling and manufacturing process of the heat dissipation component is simplified, and the costs are reduced. Notably, the power module including the voltage regulator and the semiconductor device including the integrated circuit are respectively arranged on two opposite sides of the circuit board. That is, the architecture of the heat dissipation assembly structure in the present disclosure is a vertical power supply application, which can greatly reduce the electrical connection distance from the power module to the semiconductor device, thereby greatly reducing the DC resistance generated therefrom, reducing the power loss, and greatly improving the power supply efficiency. In addition, the vertical stacking structure of the power module and the semiconductor device makes the overall design more compact and reduces the space occupancy of the entire system. Thereby, the terminal-use applications are more flexible. On the other hand, the heat dissipation component in the heat dissipation assembly structure may include a first heat dissipation element and a second heat dissipation element, which are thermally coupled to the contact surface of the power module and the contact surface of the semiconductor device, respectively, so that the heat dissipation mode in the vertical power supply application is expanded to two sides. The available space of the heat dissipation device is greatly increased. With the improvement of the efficiency of vertical power supply applications between the circuit board and the substrate, the substrate further includes an opening in the region corresponding to the power module, so that the heat dissipation component for bidirectional heat dissipation is directly fit the contact surface of the power module and the contact surface of the semiconductor device, and the heat generated by the power module and the semiconductor device is more effectively dissipated. Thereby, the temperature of the entire integrated system is reduced and the performance of the integrated system is improved. When the circuit board is connected to the substrate such as a system board through a conductive portion or a connector, the space between the power module and the substrate is limited. By using the opening design of the substrate, the heat dissipation component is combined with the stacking structure of the vertical power supply application to form a two-way heat dissipation mechanism, so that the heat dissipation problem of the heat dissipation component is solved effectively. Furthermore, since the heat dissipation element of the heat dissipation component is attached to the contact surface of the power module through the opening of the substrate, the depth of the power module relative to the opening can be adjusted, or a thermal interface material layer can be added. Furthermore, the heat dissipation requirements of the substrate can also be combined to simplify the heat dissipation assembly, reduce the module costs, and enhance the product competitiveness. The heat dissipation element of the heat dissipation component is not limited to an air-cooled heat sink or a liquid-cooled heat sink. In addition, when the circuit board and the substrate are stacked for vertical power supply, the docking distance between the circuit board and the substrate may be limited by the height of the connector. The opening of the substrate is utilized to avoid interference in the vertical direction between the heat dissipation component and the substrate in the vertical stacking structure of the heat dissipation component and the power module. Thereby, the overall height of the heat dissipation assembly structure is reduced after assembly, and the heat dissipation problem in a restricted space is solved effectively.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat dissipation assembly structure, comprising:
a circuit board, comprising a first surface and a second surface arranged opposite to each other;
a power module, disposed on the first surface of the circuit board;
a semiconductor device, disposed on the second surface of the circuit board and spatially corresponding to the power module, wherein the power module and the semiconductor device are electrically connected through the circuit board;
a plurality of CPO devices, disposed on the second surface of the circuit board and arranged adjacent to the semiconductor device;
a substrate, comprising an opening and a third surface and a fourth surface arranged opposite to each other, wherein the opening passes through the third surface and the fourth surface, the fourth surface faces the first surface of the circuit board, and a contact surface of the power module is exposed through the opening; and
a heat dissipation component, comprising a first heat dissipation element, wherein the first heat dissipation element is thermally coupled to the contact surface of the power module.

2. The heat dissipation assembly structure according to claim 1, wherein the heat dissipation component further comprises a second heat dissipation element, and the second heat dissipation element is disposed on the second surface of the circuit board and thermally coupled to a contact surface of the semiconductor device.

3. The heat dissipation assembly structure according to claim 2, wherein the heat dissipation component further comprises a thermal interface material layer, and the thermal interface material layer is arranged between the first heat dissipation element and the contact surface of the power module and/or between the second heat dissipation element and the contact surface of the semiconductor device, wherein the thermal interface material layer is a thermally conductive insulation pad, a thermally conductive insulation glue or a thermally conductive copper block.

4. The heat dissipation assembly structure according to claim 2, wherein the heat dissipation component further comprises a fixing frame, and the fixing frame is arranged between the second heat dissipation element and the second surface of the circuit board, wherein the fixing frame is located at an outer periphery of the semiconductor device.

5. The heat dissipation assembly structure according to claim 1, wherein the first surface of the circuit board and the fourth surface of the substrate are both provided with at least one conductive portion, and the conductive portion of the first surface is spatially corresponding to the conductive portion of the fourth surface.

6. The heat dissipation assembly structure according to claim 1, further comprising a connector, and the connector is arranged between the first surface of the circuit board and the fourth surface of the substrate.

7. The heat dissipation assembly structure according to claim 6, further comprising a support frame, and the support frame is disposed adjacent to the connector.

8. The heat dissipation assembly structure according to claim 6, wherein the connector comprises a first connection element and a second connection element, the first connection element is disposed on the first surface of the circuit board and arranged adjacent to the power module, and the second connection element is disposed on the fourth surface of the substrate and arranged adjacent to a lateral edge of the opening.

9. The heat dissipation assembly structure according to claim 6, wherein the connector comprises a connection element, an end of the connection element is fixed and electrically connected to one of the substrate and the circuit board, and the other end of the connection element is in contact with and electrically connected to the other of the substrate and the circuit board.

10. The heat dissipation assembly structure according to claim 6, wherein at least one of the power module and the first heat dissipation element are at least partially accommodated within the opening.

11. The heat dissipation assembly structure according to claim 10, wherein a distance from the contact surface of the power module to the first surface of the circuit board is smaller than a distance from the third surface of the substrate to the first surface of the circuit board, and is greater than a distance from the fourth surface of the substrate to the first surface of the circuit board.

12. The heat dissipation assembly structure according to claim 11, wherein a distance from an attached surface of the first heat dissipation element to the first surface of the circuit board is equal to the distance from the contact surface of the power module to the first surface of the circuit board.

13. The heat dissipation assembly structure according to claim 11, wherein a horizontal projection of the first heat dissipation element on the first surface of the circuit board is included in a horizontal projection of the opening on the first surface of the circuit board.

14. The heat dissipation assembly structure according to claim 10, wherein a distance from the contact surface of the power module to the first surface of the circuit board is greater than or equal to a distance from the third surface of the substrate to the first surface of the circuit board.

15. The heat dissipation assembly structure according to claim 10, wherein the first heat dissipation element is extended horizontally along the third surface of the substrate, and a horizontal projection of the opening on the first surface of the circuit board is included in a horizontal projection of the first heat dissipation element on the first surface of the circuit board.

16. The heat dissipation assembly structure according to claim 1, wherein a distance from an attached surface of the first heat dissipation element to the first surface of the circuit board is greater than or equal to a distance from the third surface of the substrate to the first surface of the circuit board, and a horizontal projection of the opening on the first surface of the circuit board is included in a horizontal projection of the first heat dissipation element on the first surface of the circuit board.

17. The heat dissipation assembly structure according to claim 1, wherein a horizontal projection of the semiconductor device on the first surface of the circuit board, a horizontal projection of the power module on the first surface of the circuit board, a horizontal projection of the opening on the first surface of the circuit board, and a horizontal projection of the first heat dissipation element on the first surface of the circuit board are at least partially overlapped.

18. The heat dissipation assembly structure according to claim 1, wherein the first heat dissipation element is an air-cooled heat sink or a liquid-cooled heat sink.

19. The heat dissipation assembly structure according to claim 1, wherein the substrate is a system board.

20. The heat dissipation assembly structure according to claim 1, wherein the power module is electrically connected to the semiconductor device through a conductive through hole of the circuit board.

21. A heat dissipation assembly structure, comprising:
a circuit board, comprising a first surface and a second surface arranged opposite to each other;
a power module, disposed on the first surface of the circuit board;
a semiconductor device, disposed on the second surface of the circuit board and spatially corresponding to the power module, wherein the power module and the semiconductor device are electrically connected through the circuit board;
a substrate, comprising an opening and a third surface and a fourth surface arranged opposite to each other, wherein the opening passes through the third surface and the fourth surface, the fourth surface faces the first surface of the circuit board, and a contact surface of the power module is exposed through the opening;
a conductive portion or a connector, disposed between the first surface of the circuit board and the fourth surface of the substrate; and
a heat dissipation component comprising a first heat dissipation element, wherein the first heat dissipation element is thermally coupled to the contact surface of the power module.

22. The heat dissipation assembly structure according to claim 21, wherein the semiconductor device is a graphics processing unit (GPU) chip, a central processing unit (CPU) chip, an application-specific integrated circuit (ASIC) chip, a field programmable gate array (FPGA) chip or a semiconductor die having the above functions.
